(19) United States
(12) Patent Application Publication
(10) Pub. No.: US 2010/0038686 A1
(43) Pub. Date: Feb. 18, 2010

(54) SOI SUBSTRATES AND DEVICES ON SOI SUBSTRATES HAVING A SILICON NITRIDE DIFFUSION INHIBITION LAYER AND METHODS FOR FABRICATING

(75) Inventors: Kingsuk MAITRA, Guilderland, NY (US); Andreas KERBER, White Plains, NY (US)

Correspondence Address: Ingrassia Fisher & Lorenz, P.C. (GF), 7010 E. Cochise Rd., Scottsdale, AZ, 85253, US

(73) Assignee: ADVANCED MICRO DEVICES, INC., Austin, TX (US)

(21) Appl. No.: 12/191,861

(22) Filed: Aug. 14, 2008

(51) Int. Cl. H01L 21/762; H01L 29/78

(52) U.S. Cl. 257/288; 438/458; 257/E21.568; 257/E29.255

(57) ABSTRACT

Semiconductor-on-insulator substrates and methods for fabricating semiconductor-on-insulator substrates are provided. One exemplary method comprises providing a first silicon-comprising substrate, providing a second silicon-comprising substrate, forming a first silicon nitride layer overlying the second silicon-comprising substrate, and coupling the first silicon-comprising substrate to the second silicon-comprising substrate such that the first silicon nitride layer is interposed between the two substrates.

### TECHNICAL FIELD

The present invention generally relates to semiconductor-on-insulator (SOI) substrates and devices fabricated on SOI substrates and methods for fabricating such substrates and devices, and more particularly relates to SOI substrates and devices fabricated on SOI substrates having a silicon nitride diffusion inhibition layer and methods for fabricating such SOI substrates and devices.

### BACKGROUND

The majority of present day integrated circuits (ICs) are implemented by using a plurality of interconnected field effect transistors (FETs), also called metal oxide semiconductor field effect transistors (MOSFETs or MOS transistors). The ICs are usually formed using both P-channel FETs (PMOS transistors or PFETs) and N-channel FETs (NMOS transistors or NFETs) and the IC is then referred to as a complementary MOS or CMOS circuit. Certain improvements in performance of MOS ICs can be realized by forming the MOS transistors in a thin layer of semiconductor material overlying an insulator layer. Such semiconductor-on-insulator (SOI) MOS transistors, for example, exhibit lower junction capacitance and hence can operate at higher speeds. For silicon SOI devices, the insulating layer is typically comprised of silicon oxide and is referred to as a buried oxide or BOX layer. The presence of a BOX layer generally improves inter-device isolation and thus can also facilitate denser device packing.

Further performance enhancements can be achieved by fabricating devices on SOI substrates with the overlying silicon layer having a thickness of 10 nm or less. These substrates, known as Extremely Thin SOI (ETSOI) substrates, typically feature silicon layers having thicknesses scaled down in proportion to the dimensions of other device components such as the gate length to achieve faster switching speeds. However, this structure provides only a very shallow silicon layer in which to form source and drain regions. Source/drain (S/D) dopants such as phosphorous (P) used for NFET devices and boron (B) used for PFET devices exhibit a relatively rapid diffusion rate in silicon and silicon oxide during elevated temperature processing and thus tend to migrate out of S/D regions and into the BOX layer, thus decreasing the dopant concentration in the S/D regions. Even a minimal decrease in dopant concentration resulting from this diffusion can significantly increase the external resistance, Rₑₓₜ, of MOS devices within these regions and adversely affect device performance.

Accordingly, it is desirable to provide SOI substrates and devices fabricated on such substrates having a silicon nitride diffusion inhibition layer interposed between the BOX layer and the overlying silicon layer to inhibit the diffusion of dopant species from S/D regions into the BOX layer. Further, it is desirable to provide methods for fabricating such SOI substrates and devices fabricated on such substrates. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for fabricating a silicon-on-insulator substrate in accordance with one exemplary embodiment of the invention is provided. The method comprises providing a first silicon-comprising substrate, providing a second silicon-comprising substrate, forming a first silicon nitride layer overlying the second silicon-comprising substrate, and coupling the first silicon-comprising substrate to the second silicon-comprising substrate such that the first silicon nitride layer is interposed between the two substrates.

A method for fabricating a silicon-on-insulator substrate in accordance with a further exemplary embodiment of the invention is provided. The method comprises providing a first silicon-comprising substrate, providing a second silicon-comprising substrate, forming a first silicon nitride layer overlying the first silicon-comprising substrate, coupling the first silicon nitride layer to the second silicon-comprising substrate with the first silicon nitride layer interposed therebetween, thinning the first silicon-comprising substrate, forming a gate stack overlying the first silicon-comprising substrate, and implanting impurity dopant ions into the first silicon-comprising substrate using the gate stack as an implantation mask.

A semiconductor transistor device is provided in accordance with yet another exemplary embodiment of the invention. The semiconductor transistor device comprises a silicon-comprising substrate, a silicon oxide layer disposed overlying the silicon-comprising substrate, a silicon nitride layer disposed overlying the silicon oxide layer, a crystalline silicon layer disposed overlying the silicon nitride layer, a gate stack overlying the crystalline silicon layer, and source and drain regions disposed within the crystalline silicon layer and aligned to the gate stack.

### BRIEF DESCRIPTION OF THE DRAWINGS

The present invention will hereinafter be described in conjunction with the following drawing figures, wherein like numerals denote like elements, and wherein:

FIGS. 1-5 schematically illustrate in cross-section a silicon-on-insulator substrate and methods for fabricating silicon-on-insulator substrates in accordance with exemplary embodiments of the present invention;

FIG. 6 schematically illustrates in cross-section a silicon-on-insulator substrate in accordance with another exemplary embodiment of the present invention;

FIG. 7 schematically illustrates in cross-section a silicon-on-insulator substrate in accordance with a further exemplary embodiment of the present invention;

FIG. 8 schematically illustrates in cross-section a silicon-on-insulator substrate in accordance with yet another exemplary embodiment of the present invention; and

FIGS. 9 and 10 schematically illustrate in cross-section a gate stack overlying a silicon-on-insulator substrate and methods for fabricating a gate stack overlying a silicon-on-insulator substrate in accordance with further exemplary embodiments of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

The various embodiments of the present invention result in the fabrication of an SOI substrate having a layer of silicon nitride interposed between a BOX layer and an uppermost, crystalline silicon layer of the SOI substrate. Various elements of a MOS transistor may be fabricated on and within this SOI substrate including gate stacks and source and drain regions. The nitride layer acts to inhibit the diffusion of source/drain impurity dopants such as boron or phosphorous into the BOX layer that may otherwise occur during subsequent high temperature processes such as annealing or thermal oxide growth. In this manner, the nitride layer helps to maintain dopant concentrations in S/D regions and maintain external device resistance, Rₑₓₜ, at minimal levels. Further, because the diffusion of dopants is reduced, subsequent processing may include an increased thermal budget (time and temperature) that would not be available absent the nitride layer.

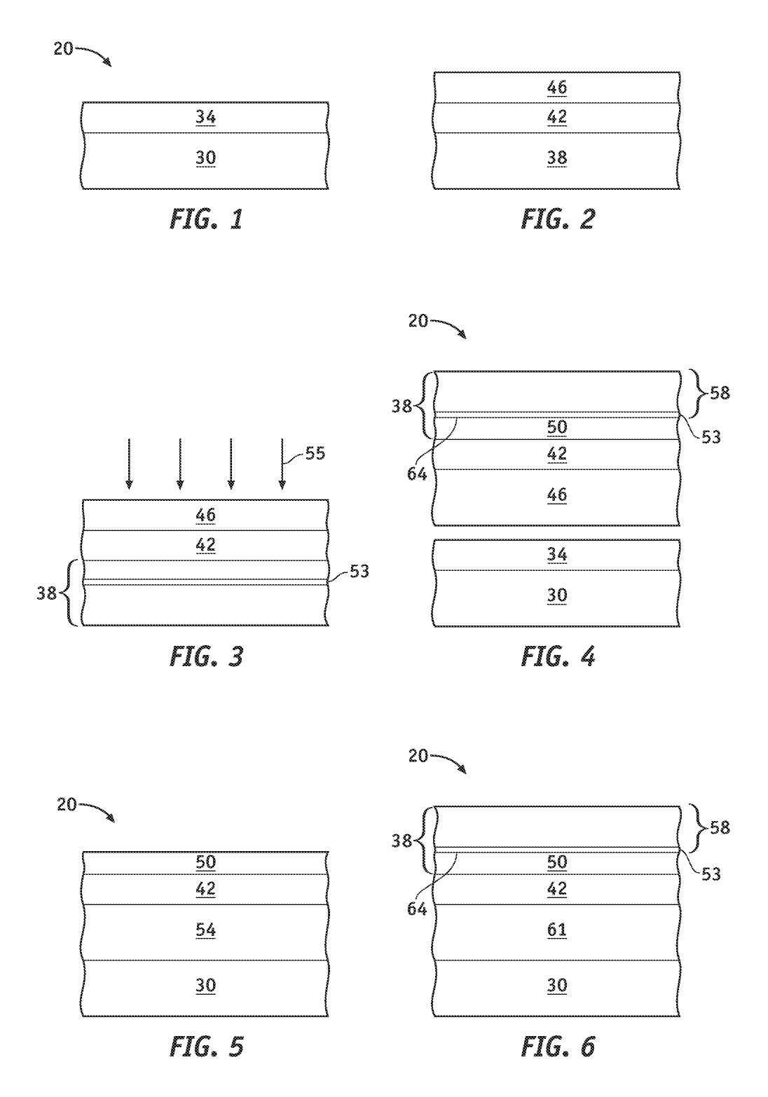

FIGS. 1-5 illustrate schematically, in cross section, methods for forming an ETSOI substrate 20 in accordance with exemplary embodiments of the invention. As illustrated in FIG. 1, the method in accordance with one embodiment of the invention includes forming a silicon oxide (SiOₓ) layer 34 overlying a silicon substrate 30. As used herein, the terms “silicon layer” and “silicon substrate” will be used to encompass the relatively pure silicon materials typically used in the semiconductor industry as well as silicon admixed with other elements such as germanium, carbon, and the like to form crystalline semiconductor material. Silicon substrate 30 preferably has a resistivity of at least about 18-33 ohms per square and may be impurity doped either N-type or P-type, but is preferably doped P-type. Silicon oxide layer 34 is formed overlying silicon substrate 30 using either a high temperature thermal oxide growth process or a chemical vapor deposition (CVD) process. A high temperature thermal oxide layer may be formed by subjecting silicon substrate 30 to temperatures ranging from about 700° C. to 1250° C. or preferably from about 900° C. to 1000° C. Alternatively, silicon oxide layer 34 may also be deposited via a low pressure CVD (LPCVD) process based upon either silane (SiH₄) or tetraethylorthosilicate Si(OC₂H₅)₄ (TEOS). As yet a further alternative, a plasma-enhanced CVD (PECVD) process may be used with SiH₄ and either oxygen (O₂) or nitrous oxide (N₂O) as reactants. The thickness of silicon oxide layer 34 is in a range of about from 10 to 200 nm, or is preferably 30-70 nm thick.

FIG. 2 illustrates, in cross section, the formation of a silicon nitride (Si₃N₄) layer 42 overlying a silicon substrate 38, in accordance with the current embodiment. Silicon substrate 38 is also a monocrystalline silicon substrate similar to silicon substrate 30 and, in various embodiments, may have a crystal orientation that is the same as, or different than that of silicon substrate 30. Silicon nitride layer 42 is deposited overlying silicon substrate 38 using an LPCVD or a plasma-enhanced CVD (PECVD) process. Because silicon nitride layer 42 is to be a barrier layer to S/D dopant diffusion, achieving a film having the lowest possible defect density is advantageous. Therefore, formation of silicon nitride layer 42 is performed preferably using an LPCVD process using silane (SiH₄) or dichlorosilane (SiCl₂H₂) with ammonia (NH₃) as reactants over a range of temperatures of about from 700° C. to 900° C. Alternatively, a PECVD process using SiH₄ and NH₃ or nitrogen (N₂) in the presence of an argon plasma may also be used. The thickness of silicon nitride layer 42 is in a range of about from 0.1 to 30 nm or preferably is about from 1 to 10 nm thick. Further, those of skill in the art will appreciate that a deposited layer of silicon nitride differs from the result obtained by simply injecting nitrogen atoms such as by ion implantation into the surface of a silicon oxide or silicon layer. A deposited silicon nitride layer such as silicon nitride layer 42 provides a better barrier layer to dopant ion migration than is achieved by a nitrogen implanted layer. In a preferred embodiment, silicon nitride layer 42 comprises a substantially stoichiometric ratio of silicon and nitrogen (Si₃N₄). Next, a silicon oxide layer 46 is deposited overlying silicon nitride layer 42 using, for example an LPCVD or PECVD process such as previously described for silicon oxide layer 34. The thickness of silicon oxide layer 46 is also in a range of about from 10 to 200 nm, or preferably is about 30 to 70 nm thick.

Referring to FIG. 3, after the formation of silicon oxide layer 46, hydrogen ions (H+), represented by arrows 55, are implanted into substrate 38. The ion implantation process implants hydrogen ions through silicon oxide layer 46 and silicon nitride layer 42 into a shallow hydrogen implanted region 53 within silicon substrate 38. Implanted hydrogen ions 55 stress the crystalline microstructure of substrate 38 within implanted region 53 causing a fracture plane to form, that in subsequent process steps can be used to facilitate cleavage of substrate 38.

Silicon oxide layers 34 and 46 then are bonded together, as illustrated in FIG. 4, using a pressure and heat treatment appropriate for bonding of silicon oxide surfaces. The heat treatment strengthens the bond and causes cleavage of silicon substrate 38 along the stressed hydrogen implanted region 53 allowing a section 58 of substrate 38 to be removed. Following the bonding and cleaving processes, silicon substrate 38 can be further thinned to remove all but a shallow crystalline silicon layer 50 adjacent to the silicon nitride layer 42. Thinning may be achieved by ion milling, chemical mechanical planarization (CMP), and/or dry silicon etching. Iterative thermal oxidation/oxide etch processes may also be used whereby a thermal oxide layer having a controlled thickness is formed at a crystalline silicon surface 64 of crystalline silicon layer 50, followed by a selective dry etch of the oxide layer. In this manner, crystalline silicon layer 50 may be reduced to the desired thickness and finally polished using an appropriate wafer polishing technique. In one embodiment, crystalline silicon layer 50 has a final thickness of about from 1 to 50 nm, or preferably is about 4 to 15 nm thick.

FIG. 5 illustrates completed SOI substrate 20 in accordance with the current embodiment. SOI substrate 20 comprises silicon substrate 30, a silicon oxide layer 54 formed by the bonding of silicon oxide layers 34 and 46, a crystalline silicon layer 50 comprised of the thinned and polished remainder of silicon substrate 38, and silicon nitride layer 42 interposed between the oxide layer 54 and the crystalline silicon layer 50.

While the formation of SOI substrate 20 as described above includes the bonding of two silicon oxide layers, it will be appreciated that SOI substrate 20 may be formed by using alternative deposition and bonding schemes. For example, referring to FIG. 6, in one embodiment, nitride layer 42, and a silicon oxide layer 61 having a thickness equal to the sum of silicon oxide layers 34 and 46 (FIG. 4) are sequentially deposited, using processes previously described, on silicon substrate 38. Silicon substrate 30 is then flip-bonded to silicon oxide layer 61 using a heat and pressure treatment appropriate for bonding silicon and silicon oxide surfaces. Following bonding, section 58 of silicon substrate 38 is removed by cleaving, thinning, and polishing, as described above, to form SOI substrate 20 (FIG. 5).

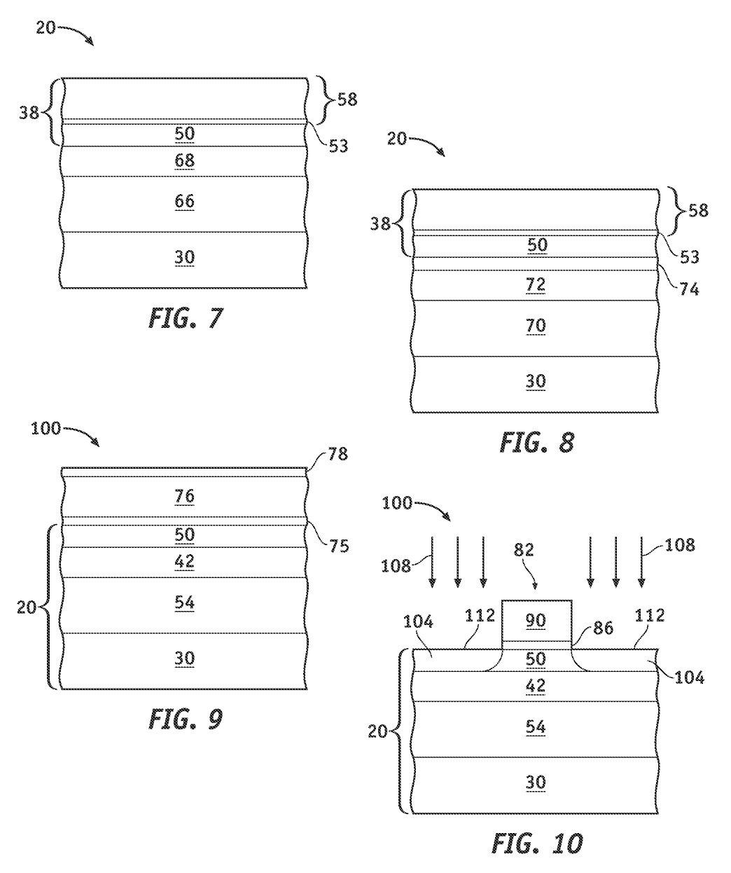

In another embodiment, referring to FIG. 7, a silicon oxide layer 66 having a thickness equal to the sum of silicon oxide layers 34 and 46 (FIG. 4) is formed overlying silicon substrate 30, followed by the deposition of a silicon nitride layer 68 overlying the silicon oxide layer 66. Silicon substrate 38 then is flip-bonded to the exposed silicon nitride layer 68 using a heat and pressure treatment appropriate for bonding crystalline silicon layer 50 to silicon nitride layer 68. As described for previous embodiments, following bonding, section 58 of silicon substrate 38 is removed leaving crystalline silicon layer 50 that may be further thinned and polished to the desired thickness to form completed SOI substrate 20.

In a further embodiment, as illustrated in FIG. 8, a silicon oxide layer 70 having a thickness equal to the sum of silicon oxide layers 34 and 46 (FIG. 4) is formed overlying silicon substrate 30, followed by the deposition of a silicon nitride layer 72 overlying the silicon oxide layer 70. A silicon nitride layer 74 is formed overlying silicon substrate 38 followed by the bonding of silicon nitride layers 72 and 74 using a heat and pressure treatment for the bonding of two silicon nitride surfaces. Substrate 38 is then cleaved to remove section 58 and further thinned and polished as needed to leave crystalline silicon layer 50 at a desired thickness to form completed SOI substrate 20.

FIGS. 9 and 10 illustrate schematically, in cross section, a method for forming a gate stack 82 of a MOS transistor 100 overlying an SOI substrate having a silicon nitride diffusion inhibition layer, such as SOI substrate 20 described above and illustrated in FIG. 5. Although the term “MOS transistor” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a silicon-comprising substrate. The embodiments herein described refer to an NMOS or a PMOS transistor. While the fabrication of only one MOS transistor is illustrated, it will be appreciated that the method depicted in FIGS. 9 and 10 can be used to fabricate any number of such transistors. Various steps in the manufacture of MOS components are well known and so, in the interest of brevity, many conventional steps will only be mentioned briefly herein or will be omitted entirely without providing the well known process details.

Referring to FIG. 9, in accordance with an exemplary embodiment of the present invention, the method begins by forming a gate insulator layer 75 overlying crystalline silicon layer 50 of SOI substrate 20. Typically, the gate insulating layer 75 can be comprised of thermally grown silicon dioxide or, alternatively (as illustrated), a deposited insulator such as a silicon oxide, silicon nitride, or the like. Deposited insulators can be deposited, for example, as previously described by chemical vapor deposition (CVD), low pressure chemical vapor deposition (LPCVD), or plasma enhanced chemical vapor deposition (PECVD). Gate insulator layer 75 preferably has a thickness of about 1 to 10 nm, depending upon the application of the transistor in the circuit being implemented.

A gate electrode layer 76 is formed overlying the gate insulating layer 75. In accordance with one embodiment of the invention, the gate electrode layer 76 comprises polycrystalline silicon preferably deposited as undoped polycrystalline silicon that is subsequently impurity doped by ion implantation. The polycrystalline silicon can be deposited by LPCVD by the hydrogen reduction of silane. A hard mask layer 78, comprised of, for example, silicon nitride or silicon oxynitride, can be deposited onto the surface of the gate electrode layer 76. The hard mask layer 78 can be deposited to a thickness of about 50 nm, also by LPCVD. Alternatively, it will be appreciated that a photoresist may be deposited onto the surface of gate layer 76 instead of hard mask layer 78.

Referring to FIG. 10, hard mask layer 78 is photolithographically patterned and the underlying gate electrode layer 76 and the gate insulating layer 75 are anisotropically etched to form a gate stack 82 having a gate insulator 86 and a gate electrode 90. The gate layer 76 can be etched in the desired pattern by, for example, reactive ion etching (RIE) using a Cl⁻ or HBr/O₂ chemistry and the hard mask layer 78 and gate insulating layer 75 (FIG. 9) can be etched, for example, by RIE in a CHF₃, CF₄, or SF₆ chemistry. The hard mask then can be removed.

Source and drain regions 104 next are formed by appropriately impurity doping crystalline silicon layer 50 in a known manner, for example, by ion implantation of dopant ions (illustrated by arrows 108), and subsequent annealing. By using the gate stack 82 as an implantation mask, the source and drain regions 104 are self-aligned thereto. For an N-channel MOS transistor the source and drain regions 104 are preferably formed by implanting phosphorus ions, although arsenic ions may also be used. For a P-channel MOS transistor, the source and drain regions 104 are preferably formed by implanting boron ions. MOS transistor 100 then may be subjected to further fabrication processes as may be required for a particular device application.

Accordingly, the source and drain regions 104 of MOS transistor 100 are substantially bounded within the crystalline silicon layer 50 by silicon nitride diffusion inhibition layer 42. This inhibition layer provides a barrier layer below S/D regions 104 wherein dopant species such as phosphorous and boron exhibit minimal diffusion therethrough. Accordingly, silicon nitride layer 42 inhibits dopants from migrating out of S/D regions 104 and into the BOX layer 54, helping to maintain S/D dopant concentration profiles at desired levels and minimizing Rₑₓₜ thereby. Further, the presence of silicon nitride layer 42 allows a greater thermal budget to be applied to the device during subsequent fabrication processes such as high temperature anneals to achieve the advantageous effects thereof.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A method for fabricating a silicon-on-insulator substrate, the method comprising the steps of:
providing a first silicon-comprising substrate;
providing a second silicon-comprising substrate;
depositing a first silicon nitride layer overlying the second silicon-comprising substrate by a low-pressure chemical vapor deposition (LPCVD) process;
forming a first silicon oxide layer overlying the first silicon nitride layer;
forming a second silicon oxide layer overlying and in contact with the first silicon-comprising substrate; and
bonding the second silicon oxide layer and the first silicon oxide layer together to form a buried oxide layer that couples the first silicon-comprising substrate to the second silicon-comprising substrate such that the first silicon nitride layer is interposed between the buried oxide layer and the second silicon-comprising substrate.

2. The method of claim 1, further comprising the step of thinning the second silicon-comprising substrate.

3. The method of claim 2, wherein the step of thinning the second silicon-comprising substrate comprises the steps of:
implanting hydrogen ions to create a stressed region within the second silicon-comprising substrate; and
cleaving the second silicon-comprising substrate in the stressed region.

4. (canceled)

5. The method of claim 4, wherein the step of coupling comprises bonding the first silicon oxide layer and the first silicon-comprising substrate together.

6. (canceled)

7. The method of claim 1, wherein the step of bonding is performed using a pressure and heat treatment:

8. The method of claim 1, wherein the step of coupling comprises bonding the first silicon nitride layer and the first silicon-comprising substrate together.

9. The method of claim 1, further comprising the step of forming a second silicon nitride layer overlying the first silicon-comprising substrate and wherein the step of coupling comprises bonding the first silicon nitride layer and the second silicon nitride layer together.

10. The method of claim 9, further comprising the step of forming a silicon oxide layer overlying the first silicon-comprising substrate before the step of forming a second silicon nitride layer.

11. The method of claim 1, wherein the step of forming a first silicon nitride layer comprises forming a silicon nitride layer having a thickness in a range of about from 0.1 nm to 30 nm.

12. (canceled)

13. A method for fabricating a semiconductor device, the method comprising the steps of:
providing a first silicon-comprising substrate;
providing a second silicon-comprising substrate;
forming a first silicon nitride layer overlying the first silicon-comprising substrate;
coupling the first silicon-comprising substrate to the second silicon-comprising substrate with the first silicon nitride layer interposed therebetween;
thinning the first silicon-comprising substrate;
forming a gate stack overlying the first silicon-comprising substrate; and
implanting impurity dopant ions into the first silicon-comprising substrate using the gate stack as an implantation mask.

14. The method of claim 13, wherein the step of coupling further comprises forming a second silicon nitride layer interposed between the first silicon nitride layer and the second silicon-comprising substrate.

15. The method of claim 13, wherein the step of coupling further comprises forming a first silicon oxide layer interposed between the second silicon-comprising substrate and the first silicon nitride layer.

16. The method of claim 15, wherein the step of coupling further comprises forming a second silicon oxide layer interposed between the first silicon oxide layer and the first silicon nitride layer.

17. The method of claim 15, wherein the step of coupling further comprises forming a second silicon nitride layer interposed between the first silicon oxide layer and the first silicon nitride layer.

18. The method of claim 13, wherein the step of forming a first silicon nitride layer comprises forming a first silicon nitride layer using an LPCVD process.

19. The method of claim 13, wherein the step of forming a first silicon nitride layer comprises forming a first silicon nitride layer having a thickness in a range of from about 0.1 nm to 30 nm.

20. (canceled)

21. The method of claim 1, wherein the first silicon nitride layer overlies the buried oxide layer.

22. The method of claim 21, wherein the first silicon nitride layer is formed in contact with the buried oxide layer and wherein the buried oxide layer directly contacts the first silicon-comprising substrate.
